(19) United States
(12) Patent Application Publication
(10) Pub. No.: US 2026/0367187 A1
(43) Pub. Date: Nov. 19, 2026

(54) SYSTEM FOR INSPECTING COUPLING STATE OF CONNECTOR AND METHOD THEREOF

(71) Applicants: Hyundai Motor Company, Seoul (KR); Kia Corporation, Seoul (KR); KTINC CO., LTD., Gyeonggi-do (KR)

(72) Inventors: Sung Yong CHO, Incheon (KR); Kyoung Tae MIN, Gyeonggi-do (KR)

(21) Appl. No.: 19/155,348

(22) PCT Filed: Dec. 27, 2023
(86) PCT No.: PCT/KR2023/021747

§ 371 Date: Aug. 11, 2025

(30) Foreign Application Priority Data
Jun. 14, 2023 (KR) 10-2023-0076208

(51) Int. Cl. G01R 31/66

(52) U.S. Cl. CPC G01R 31/66

(57) ABSTRACT

The present invention relates to a system for inspecting the coupling state of a connector and a method thereof, the system comprising: signal detection units mounted on a user's fingers to detect a plurality of assembly signals transmitted to the user's fingers when coupling a connector; a pattern data generation unit for receiving the plurality of assembly signals detected by the signal detection units and generating pattern data on the basis of the plurality of received assembly signals; and a coupling state determination unit for receiving the pattern data generated by the pattern data generation unit and determining the coupling state of the connector on the basis of the received pattern data.

### TECHNICAL FIELD

The present disclosure relates to a system for inspecting the coupling state of a connector and a method thereof and, more particularly, to a system for inspecting the coupling state of a connector and a method thereof, which are capable of determining the coupling state of a connector by receiving pattern data generated when a user performs a connector coupling operation while wearing a device for inspecting the coupling state of a connector.

### BACKGROUND ART

In the manufacturing process of automobile interior materials, electrical components installed in door trim are typically connected to cables via connectors. After a connector is fastened, a worker carries out a pull test to verify the connection is secure, that is, to determine whether the coupling state of the connector is normal. Since the process for inspecting the connection of connectors is entirely manual, the reliability of the inspection depends on the skill of the worker, which is problematic.

In response to such a problem, a method has been devised to determine the coupling state of a connector based on image data and sound data collected using a camera or a noise sensor. However, it is realistically difficult to collect all the image data of numerous connectors connected at the production site, and the accuracy of determining the coupling state of a connector is significantly reduced because sound data is difficult to collect normally due to unnecessary noise in and around the production site.

Accordingly, a method is needed to improve the accuracy of determining the connector's coupling state when a user connects a connector himself or herself, thereby improving the marketability of the connector.

The description provided above as a related art of the present disclosure is just for helping understand the background of the present disclosure and should not be construed as being included in the related art known by those skilled in the art.

### DISCLOSURE

### Technical Problem

The present disclosure aims to provide a system and a method for inspecting the coupling state of a connector, which are capable of determining the coupling state of a connector by receiving pattern data generated when a user performs a connector coupling operation while wearing a device for inspecting the coupling state of a connector.

The objectives to be achieved in the present disclosure are not limited to the ones mentioned above, and other objectives not mentioned will be clearly understood by those skilled in the art to which the present disclosure belongs from the description below.

### Technical Solution

In order to achieve the above mentioned objectives, there is provided a system for inspecting the coupling state of a connector, the system including: signal detection units mounted on fingers of a user to detect a plurality of assembly signals transmitted to the fingers of the user during an assembly process of a connector; a pattern data generation unit configured to receive the plurality of assembly signals detected by the signal detection units and to generate pattern data on the basis of the received assembly signals; and a coupling state determination unit configured to receive the pattern data generated by the pattern data generation unit and to determine a coupling state of the connector on the basis of the received pattern data.

For example, each of the signal detection units may be formed in a ring shape.

For example, the signal detection units may be respectively mounted on a thumb and an index finger of the user.

For example, the pattern data generation unit may be connected to the signal detection unit through a connection wire, and may receive the plurality of assembly signals through the connection wire.

For example, the pattern data generation unit may wirelessly transmit the generated pattern data to outside.

For example, the pattern data generation unit may generate the pattern data by synthesizing the received assembly signals.

For example, the coupling state determination unit may be configured to receive signals based on a LoRa (long range) network.

For example, the coupling state determination unit may determine the coupling state of the connector by analyzing a size of the received pattern data and comparing the size with a size of a preset reference value.

For example, the system may further include a coupling state output unit configured to output the coupling state of the connector determined by the coupling state determination unit to outside.

For example, the coupling state output unit may output a “properly coupled” notification to the outside when the coupling state of the connector is determined to be normal, and may output a vibration notification to the outside when the coupling state of the connector is determined to be abnormal.

In order to achieve the above mentioned objectives, there is provided a method for inspecting the coupling state of a connector, the method including: detecting a plurality of assembly signals transmitted to fingers of a user during an assembly process of a connector; receiving the plurality of assembly signals; generating pattern data on a basis of the received assembly signals; receiving the generated pattern data; and determining a coupling state of the connector on a basis of the received pattern data.

For example, the generating of the pattern data may further include generating the pattern data by synthesizing the received assembly signals.

For example, the determining of the coupling state of the connector may further include determining the coupling state of the connector by analyzing a size of the received pattern data and comparing the size with a size of a preset reference value.

For example, the method may further include outputting the determined coupling state of the connector to outside.

### Advantageous Effects

According to a system and a method for inspecting the coupling state of a connector of the present disclosure,

In addition,

The effects to be achieved in the present disclosure are not limited to the ones mentioned above, and other effects not mentioned will be clearly understood by those skilled in the art to which disclosure belongs from the description below.

### DESCRIPTION OF DRAWINGS

FIG. 1 is a block view showing the configuration of a system for inspecting the coupling state of a connector according to an embodiment of the present disclosure.

FIG. 2 is a view showing the system for inspecting the coupling state of a connector according to an embodiment of the present disclosure.

FIG. 3 is a view showing the configuration of a signal detection unit according to an embodiment of the present disclosure.

FIG. 4 is a graph showing an assembly signal transmitted according to a connector coupling state according to an embodiment of the present disclosure.

FIG. 5 is a block view showing the configuration of a pattern data generation unit according to an embodiment of the present disclosure.

FIG. 6 is a flowchart showing the operation of the system for inspecting the coupling state of a connector according to an embodiment of the present disclosure.

### MODE FOR INVENTION

Hereinafter, embodiments disclosed in this specification will be described in detail with reference to the attached drawings. Regardless of the numbers in the drawings, identical or similar components will be given the same reference numbers and redundant descriptions thereof will be omitted.

The suffixes “module” and “part (unit) ” used for components in the following description are given or used interchangeably only for the convenience of writing the specification, and do not have distinct meanings or roles in themselves.

In describing the embodiments disclosed in this specification, if it is determined that a detailed description of related known technologies may obscure the gist of the embodiments disclosed in this specification, the detailed description is omitted. In addition, the attached drawings are only intended to facilitate easy understanding of the embodiments disclosed in this specification, and the technical ideas disclosed in this specification are not limited by the attached drawings, and should be understood to include all modifications, equivalents, or substitutes included in the spirit and technical scope of the present disclosure. Terms including ordinal numbers, such as first, second, etc., may be used to describe various components, but the components are not limited by the terms. The terms are used only to distinguish one component from another.

When a component is referred to as being “connected” to another component, it should be understood that it may be directly connected to that other component, but that there may also be other components in between. On the other hand, when a component is referred as being “directly connected” to another component, it should be understood that there are no other components in between.

Singular expressions include plural expressions unless the context clearly indicates otherwise.

It should be understood that in this specification, the terms such as “comprise (include) ” or “have” are intended to designate that a feature, number, step, operation, component, part, or combination thereof described in the specification exists, and do not preclude the possibility of addition or existence of one or more other features or numbers, steps, operations, components, parts, or combinations thereof.

According to an embodiment of the present disclosure, it is proposed to determine the coupling state of a connector by receiving pattern data generated when a user performs a connector coupling operation while wearing a device for inspecting the coupling state of a connector.

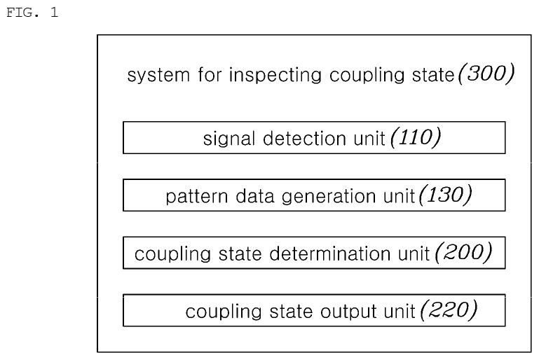

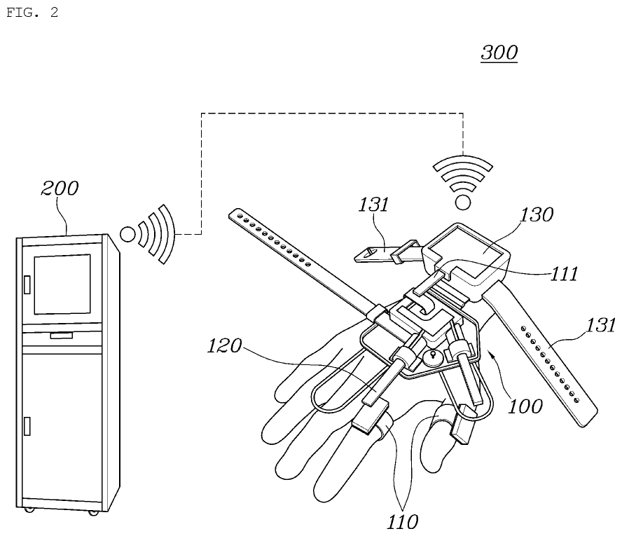

FIG. 1 and FIG. 2 are a block view and a view respectively showing the configuration of a system for inspecting coupling state of a connector according to an embodiment of the present disclosure. FIG. 1 and FIG. 2 mainly show components related to the present embodiment, and in the actual implementation of the system for inspecting the coupling state of a connector, fewer or more components than those shown in FIG. 1 and FIG. 2 may be included.

Referring to FIG. 1 and FIG. 2, a system for inspecting the coupling state of a connector according to an embodiment may include a signal detection unit 110, a pattern data generation unit 130, a coupling state determination unit 200, and a coupling state output unit 220.

To be specific, the coupling state of a connector may be determined while a user is wearing a sensor unit 100. The sensor unit 100 may include the signal detection unit 110 mounted on the user's finger, and the pattern data generation unit 130 provided on the back of the user's hand and wrist and fixed by a coupling unit 131. In addition, the sensor unit 100 may communicate with the coupling state determination unit 200, and the coupling state determination unit 200 is usually configured such that a program for analyzing pattern data and determining the coupling state of a connector is installed, and by using an industrial computer so as to satisfy the harsh conditions of a production plant.

Below, each component is described in detail.

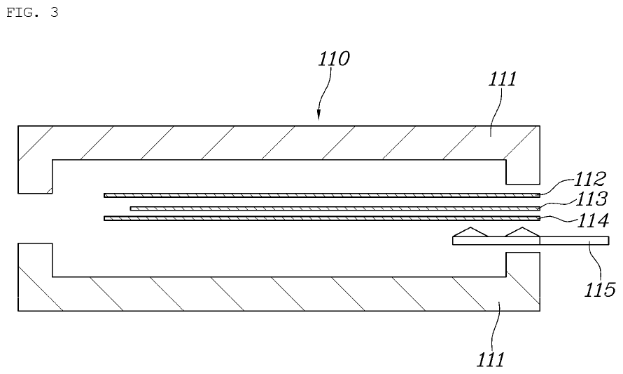

First, the signal detection unit 110 is mounted on the user's finger and may detect a plurality of assembly signals transmitted to the user's finger during the connector assembly process. The signal detection unit 110 is formed in a ring shape and may be mounted on the user's thumb and index finger. As the user repeatedly connects connectors, assembly signals are transmitted to the thumb and index finger, and the signal detection unit 110 may preprocess each detected assembly signal and transmit the signal to the pattern data generation unit 130. The configuration of the signal detection unit 110 will be described in detail with reference to FIG. 3.

FIG. 3 is a view showing the configuration of the signal detection unit 110 according to an embodiment of the present disclosure.

Referring to FIG. 3, the signal detection unit 110 is composed of a first film 112 and a third film 114 wrapping around a second film 113, a crimp contact 115, and upper and lower covers 111 surrounding the first film 112, the second film 113, the third film 114, and the crimp contact 115. It is preferable that the first film 112, the second film 113, the third film 114 are made of acrylic material, piezo material, and polyester material, respectively. The second film 113 is made of piezoelectric PVDF (polyvinylidene fluoride) with a thickness of 28 μm and is wrapped by the first film 112 and the third film 114. The crimp contact 115 may serve as a connector that transmits a signal generated from the second film 113. The end of the crimp contact 115 may be configured as a cantilever beam so that the signal from the second film 113 can be amplified. In addition, the upper and lower covers 111 may fix the crimp contact 115 in the vertical direction while protecting each film and crimp contact 115 from external impact.

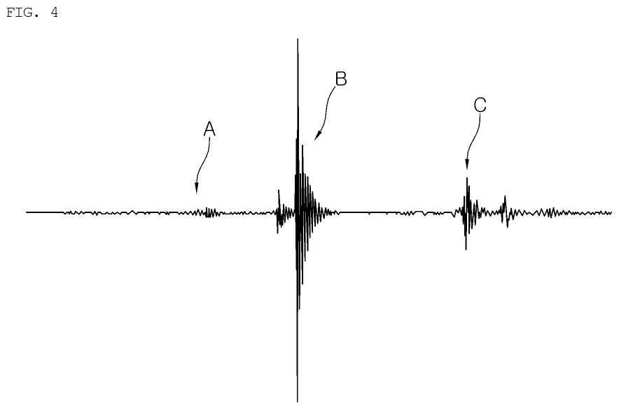

FIG. 4 is a graph showing an assembly signal transmitted according to a connector coupling state according to an embodiment of the present disclosure.

Referring to FIG. 4, the waveform of the assembly signal according to the connector coupling state can be confirmed. Part A is the signal waveform before a connector is connected, part B is the signal waveform at the moment the connector is connected, and part C is the signal waveform at the stage of confirming the connection of the connector. There is no change in the assembly signal before the connector is connected, and the change in the assembly signal is large at the moment of connection. In addition, when checking the coupling of the connector, the assembly signal changes due to the action of pulling the connector in the direction of release to determine whether the connector is securely and properly coupled. In this way, since the change in the assembly signal is clear depending on the coupling state of the connector, the accuracy of determining the coupling state of the connector may be improved.

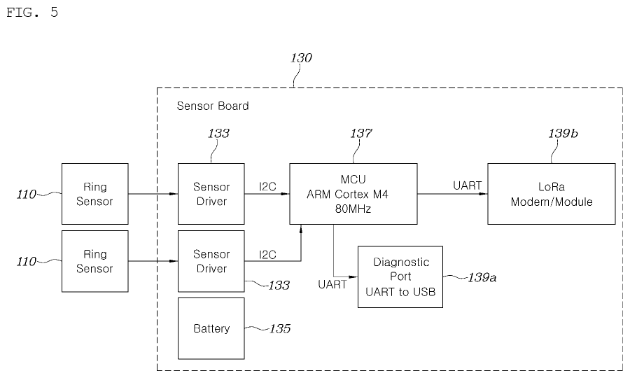

Next, as shown in FIG. 2, the pattern data generation unit 130 is connected to the signal detection unit 110 through a connection wire 120, and may receive a plurality of assembly signals through the connection wire 120. This will be described with reference to FIG. 5.

FIG. 5 is a block view showing the configuration of the pattern data generation unit 130 according to an embodiment of the present disclosure.

Referring to FIG. 5, the internal configuration of the pattern data generation unit 130 may be confirmed. The pattern data generation unit 130 is configured in the form of a sensor board and may receive an assembly signal of the signal detection unit 110 by utilizing a LoRa (long range) network. The LoRa network is optimized for security, enables long-distance communication, and allows data collection through a plurality of sensors.

The pattern data generation unit 130 may read the change of the signal detection unit 110 through a sensor driver 133. In particular, an MCU 137 may perform the overall functions of extended commands and units, data collection and processing commands, and data wireless communication through a LoRa module. The pattern data generation unit 130 may perform firmware setting and update by means of a diagnostic port 139a and supply power in the form of a battery 135. In addition, a communication module 139b may connect to a LoRa gateway and enable data to be transmitted at a high sampling rate (800 Hz or higher).

In addition, the pattern data generation unit 130 may receive a plurality of assembly signals detected by the signal detection unit 110 and generate pattern data on the basis of the plurality of assembly signals received. In this case, the pattern data generation unit 130 may generate pattern data by synthesizing the assembly signals transmitted to the thumb and index finger respectively, and wirelessly transmit the generated pattern data to the outside.

Next, the coupling state determination unit 200 may receive pattern data generated by the pattern data generation unit 130. The coupling state determination unit 200 is configured to receive a signal based on the LoRa network in order to receive pattern data wirelessly transmitted externally by means of the pattern data generation unit 130, and may determine the coupling state of a connector based on the received pattern data.

The coupling state determination unit 200 may determine the connector coupling state by analyzing the size of the received pattern data and comparing the result with the size of a preset reference value. £ For example, the coupling state determination unit 200 may determine that the connector coupling state as “normal (properly coupled)” if the size of the pattern data is larger than the size of the reference value, and may determine that the connector coupling state as “unconnected” if the size of the pattern data is smaller than the size of the reference value. This allows the pattern data generated during the connector coupling operation to be received and the connector coupling state to be determined in real time.

In addition, the coupling state output unit 220 may output the coupling state of a connector determined by the coupling state determination unit 200 to the outside. In this case, the coupling state output unit 220 may be provided as a separate configuration or, the function of the coupling state output unit 220 may be performed by the pattern data generation unit 130 or the coupling state determination unit 200. In the case that the connector's coupling state is determined to be normal, the coupling state output unit 220 may output a “properly coupled” notification to the outside. In the case that the connector's coupling state is determined to be abnormal, a vibration notification is sent to the user so that the user can recheck the connector's coupling state to ensure normal connection.

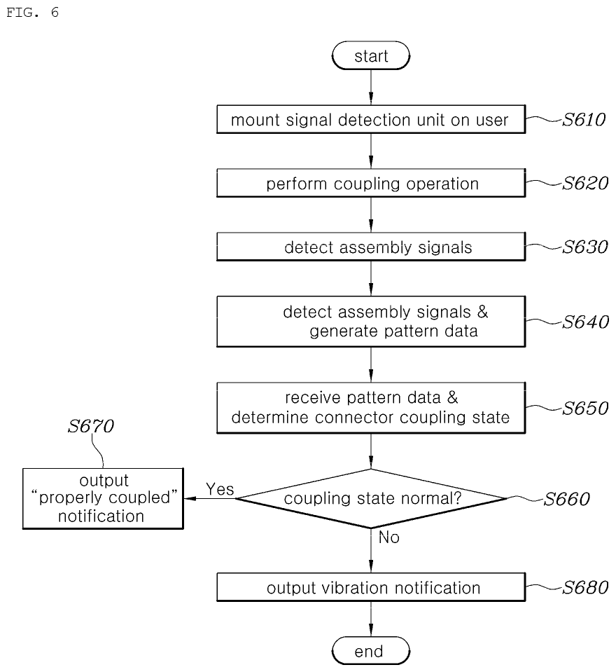

Based on the configuration of the system for inspecting the coupling state of a connector described above, a connector coupling state inspection method according to an embodiment is explained with reference to FIG. 6.

FIG. 6 is a flowchart showing the operation of the system for inspecting the coupling state of a connector according to an embodiment of the present disclosure.

Referring to FIG. 6, first, the user may wear the signal detection unit 110 on his or her fingers (S610). While wearing the signal detection unit 110, the user performs the connector connection work (S620), and as the work is performed, the signal detection unit 110 may detect a plurality of assembly signals through the thumb and index finger (S630). Thereafter, the pattern data generation unit 130 may receive a plurality of assembly signals and generate pattern data on the basis of the received assembly signals (S640). Thereafter, the coupling state determination unit 200 may receive pattern data wirelessly transmitted to the outside and determine the coupling state of the connector on the basis of the received pattern data (S650). The coupling state output unit 220 may output a “properly coupled” notification to the outside when the connector's coupling state is determined to be normal (YES of S660), and when the connector's coupling state is determined to be abnormal (NO of S660), the coupling state output unit 220 may send a vibration notification to the user so that the user can recheck the connector's coupling state to ensure proper connection (S680).

According to the embodiments of the present disclosure described so far, it is possible to determine the coupling state of a connector by receiving pattern data generated when a user performs a connector coupling operation while wearing a device for inspecting the coupling state of a connector. Furthermore, the accuracy of determining the connector's coupling state may be increased, thereby improving the marketability of the connector.

While the present disclosure has been illustrated and described with respect to specific embodiments thereof, it will be apparent to those skilled in the art that the present disclosure may be variously improved and modified without departing from the technical spirit of the present disclosure as defined by the following claims.

### DESCRIPTION OF REFERENCE NUMERALS

100: sensor unit
110: signal detection unit
111: upper and lower covers
112: first film
113: second film
114: third film
115: crimp contact
120: connection wire
130: pattern data generation unit
131: coupling unit
133: sensor driver
135: battery
137: MCU
139a: diagnostic port
139b: communication module
200: coupling state determination unit
220: coupling state output unit

What is claimed is

1. A system for inspecting a coupling state of a connector, the system comprising:
signal detection units mounted on fingers of a user to detect a plurality of assembly signals transmitted to the fingers of the user during an assembly process of the connector;
a pattern data generation unit configured to receive the plurality of assembly signals detected by the signal detection units and to generate pattern data on a basis of the received assembly signals; and
a coupling state determination unit configured to receive the pattern data generated by the pattern data generation unit and to determine the coupling state of the connector on a basis of the received pattern data.

2. The system of claim 1, wherein each of the signal detection units is formed in a ring shape.

3. The system of claim 1, wherein the signal detection units are respectively mounted on a thumb and an index finger of the user.

4. The system of claim 1, wherein the pattern data generation unit is connected to the signal detection unit through a connection wire, and receives the plurality of assembly signals through the connection wire.

5. The system of claim 1, wherein the pattern data generation unit is configured to wirelessly transmit the generated pattern data to outside.

6. The system of claim 1, wherein the pattern data generation unit is configured to generate the pattern data by synthesizing the received assembly signals.

7. The system of claim 1, wherein the coupling state determination unit is configured to receive signals based on a LoRa (long range) network.

8. The system of claim 1, wherein the coupling state determination unit is configured to determine the coupling state of the connector by analyzing a size of the received pattern data and comparing the size with a size of a preset reference value.

9. The system of claim 1, further comprising:
a coupling state output unit configured to output the coupling state of the connector determined by the coupling state determination unit to outside.

10. The system of claim 9, wherein the coupling state output unit is configured to output a “properly coupled” notification to the outside when the coupling state of the connector is determined to be normal, and to output a vibration notification to the outside when the coupling state of the connector is determined to be abnormal.

11. A method for inspecting a coupling state of a connector, the method comprising:
detecting a plurality of assembly signals transmitted to fingers of a user during an assembly process of the connector;
receiving the plurality of assembly signals;
generating pattern data on a basis of the received assembly signals;
receiving the generated pattern data; and
determining the coupling state of the connector on a basis of the received pattern data.

12. The method of claim 11, wherein the generating the pattern data comprises:
generating the pattern data by synthesizing the received assembly signals.

13. The method of claim 11, wherein the determining the coupling state of the connector comprises:
determining the coupling state of the connector by analyzing a size of the received pattern data and comparing the size with a size of a preset reference value.

14. The method of claim 11, further comprising:
outputting the determined coupling state of the connector to outside.
